(19) United States
(12) Patent Application Publication
(10) Pub. No.: US 2011/0051387 A1
(43) Pub. Date: Mar. 3, 2011

(54) METHOD FOR ELECTROLESS NICKEL-PALLADIUM-GOLD PLATING, PLATED PRODUCT, PRINTED WIRING BOARD, INTERPOSER AND SEMICONDUCTOR APPARATUS

(75) Inventors: Kenya TACHIBANA, Tokyo (JP); Teppei ITO, Tokyo (JP); Yasuaki MITSUI, Tokyo (JP)

(73) Assignee: SUMITOMO BAKELITE COMPANY, LTD., Tokyo (JP)

(21) Appl. No.: 12/852,522

(22) Filed: Aug. 9, 2010

(30) Foreign Application Priority Data
Aug. 10, 2009 (JP) 2009-185622

(51) Int. Cl. H05K 1/09; H05K 7/00; H05H 1/00

(52) U.S. Cl. 361/783; 174/257; 427/537

(57) ABSTRACT

An object of the present invention is to provide an electroless nickel-palladium-gold plating method which is able, when performed on a plating target surface such as terminals of a printed wiring board, terminals of other electronic components, and other resin substrates with a fine metal pattern, to prevent abnormal metal deposition on a resin surface which is an undercoat and to provide a high-quality plated surface. Another object of the present invention is to provide a plated product with a high-quality plated surface, particularly such as an interposer and motherboard, and a semiconductor apparatus using the same. These objects were achieved by the electroless nickel-palladium-gold plating method of the present invention, which is a method for plating target objects such as terminals of a printed wiring board and in which at least one surface treatment selected from a treatment with a solution of pH 10 to 14 and a plasma treatment is performed at an optional step after the step of providing a palladium catalyst and before the step of performing electroless palladium plating.

### TECHNICAL FIELD

The present invention relates to a method for electroless nickel-palladium-gold plating, a plated product produced by the method, especially a printed wiring board such as motherboard and interposer, and a semiconductor apparatus comprising the printed wiring board.

### BACKGROUND ART

A motherboard and interposer are known as the printed wiring board of a semiconductor apparatus. The interposer is a printed wiring board similar to the motherboard; however, it is present between a semiconductor device (bare chip) or semiconductor package and a motherboard and mounted on the motherboard.

As well as the motherboard, the interposer can be used as a semiconductor package mounting substrate. It can be used as a package substrate or module substrate, which is a unique application of the interposer.

The package substrate means that the interposer is used as the substrate of a semiconductor package. There are two types of package substrates: a first type in which a semiconductor device is mounted on a lead frame and they are connected to each other by wire bonding and encapsulated with a resin; and a second type in which, using an interposer as the package substrate, a semiconductor device is mounted on the interposer and they are connected to each other by a method such as wire bonding and encapsulated with a resin.

In the case of using the interposer as the package substrate, connecting terminals to the motherboard can be arranged on a flat surface of the semiconductor package, the surface being on a side to be connected to the motherboard (on the undersurface of the interposer). Also, it is possible to bridge a wire size gap between the semiconductor device and the motherboard by increasing the wire size gradually from a side of the interposer which will be connected to the semiconductor device to a side of the same which will be connected to the motherboard.

Now, lines and spaces of a circuit inside the semiconductor device reach submicron levels, and connecting terminals to be connected thereto, which is of a circuit of an outermost layer on one side of the interposer, the side being to be connected to the semiconductor device, have lines and spaces (L/S) of several ten micrometers/several ten micrometers. On the other hand, connecting terminals of a circuit of an outermost layer of the interposer, the layer being on a side to be connected to the motherboard, have lines and spaces (L/S) of several hundred micrometers/several hundred micrometers, and connecting terminals of a circuit of an outermost layer of the motherboard, the layer being on a side to be connected to the interposer, have lines and spaces (L/S) of several hundred micrometers/several hundred micrometers, also.

The module substrate means that it is used as a substrate on which several semiconductor packages or semiconductor devices to be packaged are mounted in a single module.

In keeping with this technical trend, an interposer which is a multilayer printed wiring board is used to respond to further development of high density wiring and complex circuits.

Terminals of a circuit of an outermost layer of a printed wiring board (such as interposer and motherboard) are plated with gold in order to ensure reliability of connections such as solder bonding and wire bonding. A typical gold plating method is an electroless nickel-electroless palladium-electroless gold plating method (hereinafter electroless nickel-electroless palladium-electroless gold plating is referred to as electroless nickel-palladium-gold plating). In this method, a pretreatment is performed on terminals by an appropriate method such as an application of a cleaner and then a palladium catalyst is provided to the terminals; moreover, electroless nickel plating, electroless palladium plating and electroless gold plating are performed thereon in sequence.

ENEPIG (electroless nickel-electroless palladium-immersion gold) method is such that immersion gold plating is performed in the electroless gold plating step of the electroless nickel-palladium-gold plating method (Patent Literature 1).

Anti-diffusion properties and corrosion resistance of a conductor material in the terminals are improved by providing an electroless palladium plating film between an electroless nickel plating film and electroless gold plating film, which are undercoats. It is possible to prevent the nickel plating film (undercoat) from being diffused, so that there is an increase in reliability of Au—Au bonding. Also, it is possible to prevent gold-induced nickel oxidization, so that there is an increase in reliability of lead-free solder bonding to which large heat load is applied.

### CITATION LIST

### Patent Literature

Patent Literature 1: Japanese Patent Application Laid-Open (JP-A) No. 2008-144188

### SUMMARY OF INVENTION

### Technical Problem

The inventors of the present invention have found out that when electroless nickel-palladium-gold plating is performed on terminals of a circuit of an outermost layer of a printed wiring board, in the following electroless palladium plating step, a large amount of palladium metal is abnormally deposited in an area of a resin surface of an insulating layer or substrate, the area being around the terminals and the resin surface supporting the conductive circuit, thereby degrading the quality of a plated surface and, in a severe case, causing a short-circuit between adjacent terminals.

Specially, connecting terminals of a circuit of an outermost layer of an interposer for package substrate, the layer being on a side to be connected to a semiconductor device, have narrow lines and spaces (L/S) of several ten micrometers/several ten micrometers, so that a short circuit is likely to occur.

The present invention was achieved to solve the above problems. An object of the present invention is to provide an electroless nickel-palladium-gold plating method which is intended to plate plating objects such as terminals of a printed wiring board, a surface of a conductive circuit of electronic components other than a printed wiring board, and a surface of a fine metal pattern supported on a resin substrate, and which prevents, when preformed on such plating target surfaces, abnormal metal deposition on a resin surface which is an undercoat and gives a high-quality plated surface, therefore.

In addition, another object of the present invention is to provide a plated product which has an electroless nickel-palladium-gold plating film on a surface of a fine metal pattern and a high-quality plated surface, especially such as an interposer and motherboard, and also to provide a semiconductor apparatus comprising the interposer or motherboard.

### Solution to Problem

The plating method of the present invention of a method for electroless nickel-palladium-gold plating on a substrate with a fine metal pattern in which the fine metal pattern is provided on a supporting resin surface, the method comprising the steps of providing a palladium catalyst to the fine metal pattern and then performing electroless nickel-palladium-gold plating on the fine metal pattern, wherein at least one surface treatment selected from a treatment with a solution of pH 10 to 14 and a plasma treatment is performed on the substrate with the fine metal pattern at an optional step after the step of providing the palladium catalyst and before the step of performing electroless palladium plating.

### ADVANTAGEOUS EFFECTS OF INVENTION

It is possible by the plating method of the present invention to prevent abnormal metal deposition on a resin surface around terminals and to form a high-quality Ni—Pd—Au plating film on surfaces of the terminals. Thus, a high-quality plated surface and product are obtained.

The plating method of the present invention can be suitably applied to terminals of a circuit of an outermost layer of a printed wiring board such as motherboard and interposer. Especially, it can be suitably applied to terminals of an interposer. A semiconductor device or semiconductor package is mounted on a printed wiring board having terminals plated by the plating method of the present invention, thereby obtaining a semiconductor apparatus with high connection reliability.

Also, the plating method of the present invention can be suitably applied to a surface of a conductive circuit of electronic components other than a printed wiring board. Furthermore, in various application fields other than electronic components, the plating method of the present invention gives a high-quality plated surface by plating a fine metal pattern supported on a resin substrate.

### BRIEF DESCRIPTION OF DRAWINGS

In the accompanying drawings,

FIG. 1 is a view schematically showing an example of a multilayer mounting structure of a semiconductor apparatus;

FIG. 2 is a view schematically showing an example of a semiconductor package comprising an interposer;

FIG. 3 is a block diagram showing steps of a plating method according to the present invention;

FIG. 4 shows a comb-shaped copper circuit formed on each of test pieces used in Examples;

FIG. 5 is an electron micrograph of terminals of a plated product obtained in Comparative Example 1;

FIG. 6 is an electron micrograph of terminals of a plated product obtained in Example 1;

FIG. 7 is an electron micrograph of terminals of a plated product obtained in Example 2;

FIG. 8 is an electron micrograph of terminals of a plated product obtained in Example 3;

FIG. 9 is an electron micrograph of terminals of a plated product obtained in Example 4; and

FIG. 10 is an electron micrograph of terminals of a plated product obtained in Example 6.

### REFERENCE SIGNS LIST

1. Semiconductor Apparatus
2. Motherboard
3. Semiconductor package
4. Interposer
5. Semiconductor device
6. Connecting terminal of the motherboard
7 (7a and 7b). Solder resist layer of the motherboard
8. Core substrate of the interposer
9 (9a, 9b and 9c). Conductive circuit layer on a semiconductor device-mounted side of the interposer
10 (10a, 10b and 10c). Conductive circuit layer on a motherboard-connected side of the interposer
11 (11a and 11b). Connecting terminal of the interposer
12 (12a and 12b). Solder resist layer of the interposer
13. Solder ball
14. Electrode pad of the semiconductor device
15. Solder ball
16. Encapsulating material
20. Semiconductor package
21. Interposer
22. Semiconductor device
23 (23a and 23b). Connecting terminal of the interposer
24 (24a and 24b). Solder resist layer of the interposer
25. Electrode pad of the semiconductor device
26. Gold wire
27. Layer of cured die bond material
28. Solder ball
29. Encapsulating material

### DESCRIPTION OF EMBODIMENTS

The plating method of the present invention is a method for electroless nickel-palladium-gold plating on a substrate with a fine metal pattern in which the fine metal pattern is provided on a supporting resin surface, the method comprising the steps of providing a palladium catalyst to the fine metal pattern and then performing electroless nickel-palladium-gold plating on the fine metal pattern, wherein at least one surface treatment selected from a treatment with a solution of pH 10 to 14 and a plasma treatment is performed on the substrate with the fine metal pattern at an optional step after the step of providing the palladium catalyst and before the step of performing electroless palladium plating.

The plating method of the present invention can be suitably applied to terminals of a circuit of an outermost layer of a printed wiring board. It is possible by the plating method to prevent abnormal metal deposition on a resin surface around terminals and to form a high-quality Ni—Pd—Au plating film on surfaces of the terminals. Thus, a high-quality plated surface is obtained.

Specially, terminals of a circuit of an outermost layer of an interposer for package substrate, the layer being on a side to be connected to a semiconductor device, have such narrow lines and spaces, so that there is a problem that a short circuit is likely to occur when abnormal metal deposition occurs on a resin surface between the terminals (lines). The plating method of the present invention is particularly effective for such terminals having narrow lines and spaces and can increase product yield.

Also, the plating method of the present invention can be suitably applied to a surface of a conductive circuit of electronic components other than a printed wiring board. Furthermore, in various application fields other than electronic components, the plating method of the present invention gives a high-quality plated surface by plating a fine metal pattern supported on a resin substrate.

Hereinafter, the plating method of the present invention will be described using a case example in which a copper circuit is formed on an outermost layer of a printer wiring board and terminals of the copper circuit are plated.

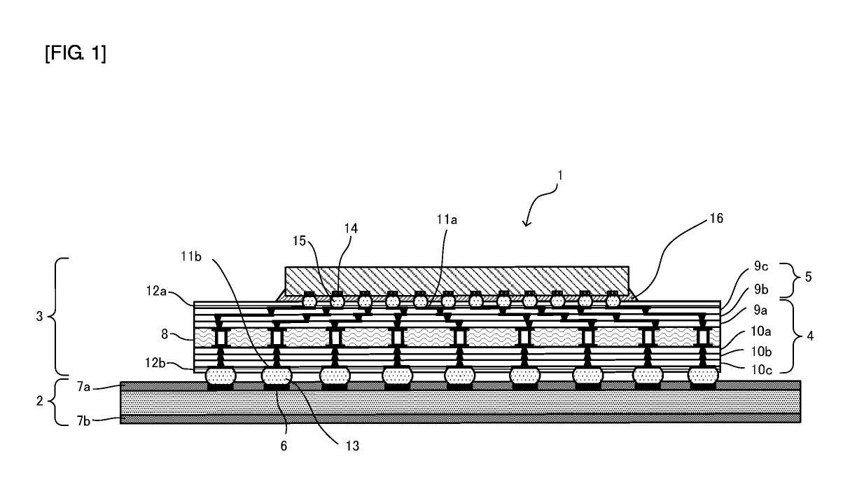

FIG. 1 is a view schematically showing a structure of a semiconductor apparatus comprising a semiconductor package using an interposer as a package substrate and a motherboard on which the semiconductor package is mounted.

In FIG. 1, a semiconductor apparatus 1 comprises a motherboard 2 and a semiconductor package 3 mounted on the motherboard.

Both surfaces of the motherboard 2 are covered with solder resist layers 7a and 7b each. Connecting terminals 6 of a circuit of an outermost layer of the motherboard, the layer being on aside that is connected to the semiconductor package, are exposed from the solder resist layer 7a.

The semiconductor package 3 is an area array-type package in which connecting terminals 11b are arranged on an undersurface of the package and the connecting terminals 11b on the undersurface of the package are solder-connected to the connecting terminals 6 on a package-mounted side of the motherboard 2 through solder balls 13.

The semiconductor package 3 comprises an interposer 4 used as the package substrate and a semiconductor device 5 mounted on the interposer.

The interposer 4 is a multilayer printed wiring board. Three conductive circuit layers 9a, 9b and 9c are overlaid in sequence on a semiconductor device-mounted side of a core substrate 8 of the interposer, while three conductive circuit layers 10a, 10b and 10c are overlaid on a motherboard-connected side of the core substrate. The semiconductor device-mounted side of the interposer 4 shows that a wire size is gradually decreased through the three conductive circuit layers 9a, 9b and 9c. Circuits of outermost layers on both surfaces of the interposer 4 are covered with solder resist layers 12a and 12b each, while connecting terminals 11a and the connecting terminals 11b are exposed from solder resist layers 12a and 12b, respectively.

The connecting terminals 11a of the circuit of the outermost layer on the semiconductor device-mounted side of the interposer 4 are likely to have lines and spaces (L/S) of 10 to 50 μm/10 to 50 μm. On the other hand, the connecting terminals 11b of the circuit of the outermost layer on the motherboard-connected side of the interposer 4 are likely to have lines and spaces (L/S) of 300 to 500 μm/300 to 500 μm. The connecting terminals 6 of the circuit of the outermost layer on the package-mounted side (interposer-connected side) of the motherboard 2 are likely to have lines and spaces (L/S) of 300 to 500 μm/300 to 500 μm.

The semiconductor device 5 has electrode pads 14 on an undersurface thereof. The electrode pads 14 are solder-connected to the connecting terminals 11a of the circuit of the outermost layer on the semiconductor device-mounted side of the interposer 4 through solder balls 15.

A gap between the interposer 4 and the semiconductor device mounted thereon is encapsulated with an encapsulating material 16 such as an epoxy resin.

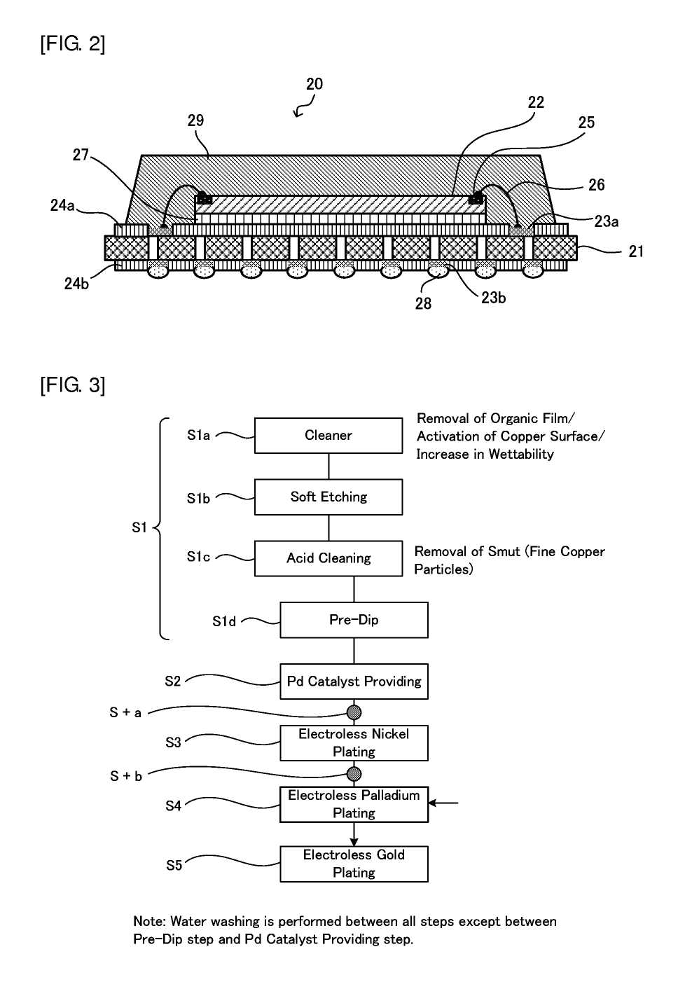

FIG. 2 is a view schematically showing a structure of a different type of semiconductor package using an interposer as a package substrate (wire bonding-type semiconductor package).

In FIG. 2, a semiconductor package 20 comprises an interposer 21 used as the package substrate and a semiconductor device 22 mounted on the interposer.

The semiconductor package 20 is an area array-type package in which connecting terminals 23b are arranged on an undersurface of the package and solder balls 28 are disposed on the connecting terminals 23b on the undersurface of the package.

A detailed laminate structure of the interposer 21 is omitted herein; however, the interposer 21 is a multilayer printed wiring board similar to the one shown in FIG. 1. Circuits of outermost layers on both surfaces of the interposer are covered with solder resist layers 24a and 24b each, while connecting terminals 23a and the connecting terminals 23b are exposed from solder resist layers 24a and 24b, respectively.

The semiconductor device 22 is bonded to a semiconductor device-mounted side of the interposer 21 through a layer of cured die bond material 27, such as a layer comprising an epoxy resin.

The semiconductor device 22 has electrode pads 25 on an upper surface thereof. The electrode pads 25 are connected to the connecting terminals 23a of the circuit of the outermost layer on the semiconductor device-mounted side of the interposer 21 through gold wires 26.

The semiconductor device-mounted side of the semiconductor package 20 is encapsulated with a sealing material 29 such as an epoxy resin.

A printed wiring board like the interposers shown in the figures can be obtained by building up several conductive circuit layers on a core substrate such as a copper clad epoxy laminate based on glass fabrics. The conductive circuit layers can be formed by a conventionally-known method such as semi-additive method. As the conductive circuit layer, one that is obtained by forming a conductive layer comprising a foil or deposit of copper or copper alloy on a core substrate or insulating layer and then etching the conductive layer in a predetermined pattern, is common. However, the present invention is applicable to anything on which electroless nickel-palladium-gold plating can be applied, even one that is formed by printing a conductive paste.

After a conductive circuit is formed on an outermost layer of an interposer, the layer being on a side to be connected to a semiconductor device, a solder resist layer is formed on a pattern of the conductive circuit to cover most of the circuit, while an area including terminals of the circuit are left exposed for connection. The plating method of the present invention can be applied to the terminals.

In a conductive circuit of an outermost layer of the interposer, the layer being on a side to be connected to a motherboard, and also in a conductive circuit of an outermost layer of the motherboard, the layer being on a side to be connected to the interposer, only an area including terminals can be exposed as above to cover other area with a solder resist layer, and the plating method of the present invention can be applied to the terminals.

FIG. 3 is a block diagram showing steps of the plating method of the present invention.

When terminals of a copper circuit of an outermost layer of a printed wiring board are plated by the present invention, as a pretreatment prior to the step of providing the palladium catalyst, surface treatment can be performed on the terminals by one or more methods as needed. As the pretreatment, FIG. 3 shows a cleaner treatment step (S1a), soft etching step (S1b), acid cleaning step (S1c) and pre-dip step (S1d). Other treatment(s) can be performed as needed.

After the pretreatment, a palladium catalyst is provided and electroless nickel-palladium-gold plating is performed, thereby forming a nickel-palladium-gold (Ni—Pd—Au) plating film.

In the plating method of the present invention, a pretreatment step (S1), palladium catalyst providing step (S2), electroless nickel plating step (S3), electroless palladium plating step (S4) and electroless gold plating step (S5) can be performed in conventional manners.

In the present invention, one or more treatments (abnormal deposition preventing treatments) selected from the treatment with the solution of pH 10 to 14 and the plasma treatment is performed, at an optional step after the step of providing the palladium catalyst and before the step of performing electroless palladium plating in the above process. Because of this, abnormal deposition is prevented in the electroless palladium plating step.

The optional step after the step of providing the palladium catalyst and before the step of performing electroless palladium plating refers to a step between the palladium catalyst providing step and the electroless nickel plating step (step S+a) and a step between the electroless nickel plating step and the electroless palladium plating step (step S+b) in FIG. 3.

In the case of adding two or more treatments to prevent abnormal deposition, they can be performed appropriately in different orders. Also, two or more abnormal deposition preventing treatments can be allotted to the steps (S+a) and (S+b) respectively.

Hereinafter, steps S1 to S5 will be described in sequence, as well as the abnormal deposition preventing steps (S+a and S+b) which are characteristic of the present invention.

### <Pretreatment Step (S1)>

(1) Cleaner treatment step (S1a)

The cleaner treatment step (S1a) is a pretreatment and performed to remove an organic film from the surface of the terminals, activate the surface of the terminals and increase wettability of the surface of the terminals by bringing an acid or alkali cleaner solution into contact with the surface of the terminals.

The acid cleaner is mainly used to etch a very thin part (very shallow part) of the terminal surface and thus to activate the surface. A solution containing an oxycarboxylic acid, ammonia, sodium chloride and surfactant, such as ACL-007 manufactured by C. Uyemura & Co., Ltd., is used as an acid cleaner which is effective for copper terminals. A solution containing a sulfuric acid, surfactant and sodium chloride (such as ACL-738 manufactured by C. Uyemura & Co., Ltd.) can be used as a different type of acid cleaner which is effective for copper terminals. This solution gives high wettability.

The alkali cleaner is mainly used to remove an organic film. A solution containing a nonionic surfactant, 2-ethanolamine and diethylene triamine (such as ACL-009 manufactured by C. Uyemura & Co., Ltd.) is used as an alkali cleaner which is effective for copper terminals.

The cleaning step can be performed by bringing any of the above cleaner solutions into contact with the terminals by an immersion method, spraying method, etc., and then washing the terminals with water.

### (2) Soft Etching Step (S1b)

The soft etching step (S1b) is a pretreatment and performed to etch a very thin part of the terminal surface and thus to remove an oxidized film. An acid solution containing a sodium persulfate and sulfuric acid is used as a soft etching solution which is effective for copper terminals.

The soft etching step can be performed by bringing the soft etching solution into contact with the terminals by an immersion method, spraying method, etc., and then washing the terminals with water.

### (3) Acid Cleaning Step (S1c)

The acid cleaning step (S1c) is a pretreatment and performed to remove smut (fine copper particles) from the terminal surface or a resin surface around the terminals.

A sulfuric acid is used as an acid cleaning solution effective for copper terminals.

The acid cleaning step can be performed by bringing the acid cleaning solution into contact with the terminals by an immersion method, spraying method, etc., and then washing the terminals with water.

### (4) Pre-Dip Step (S1d)

The pre-dip step (S1d) is a pretreatment and a step of immersing the terminals in a sulfuric acid prior to the palladium catalyst providing step, the acid concentration of the sulfuric acid being almost the same as a catalyst providing solution. The pre-dip step is performed to increase hydrophilicity of the terminal surface and thus increase adhesion to Pd ions that are contained in the catalyst providing solution, to prevent washing water used in a preceding step from being mixed with the catalyst providing solution and thus make the catalyst providing solution repeatedly usable, and to remove an oxidized film. A sulfuric acid is generally used as a pre-dip solution.

The pre-dip step can be performed by immersing the terminals in the pre-dip solution. Washing of the terminals with water is not performed after the pre-dip step.

### <Palladium Catalyst Providing Step (S2)>

An acid solution containing Pd²⁺ ions (catalyst providing solution) is brought into contact with the terminal surface to substitute the copper of the terminal surface with the Pd²⁺ ions and deposit metallic Pd by ionization tendency (Cu+Pd²⁺→Cu²⁺+Pd). The Pd thus attached to the terminal surface acts as a catalyst for electroless plating. Palladium sulfate or palladium chloride can be used as a palladium salt, which is a source of Pd²⁺ ion supply.

Palladium sulfate has lower adsorbability than palladium chloride, so that the resulting Pd is likely to be removed; therefore, palladium sulfate is suitable for thin line forming. As a palladium sulfate-containing catalyst providing solution effective for copper terminals, there may be used a strong acid solution containing a sulfuric acid, palladium salt and copper salt (such as KAT-450 manufactured by C. Uyemura & Co., Ltd.) or a strong acid solution containing an oxycarboxylic acid, sulfuric acid and palladium salt (such as MNK-4 manufactured by C. Uyemura & Co., Ltd.)

On the other hand, palladium chloride has strong adsorbability and substitution properties, so that the resulting Pd is resistant to removal; therefore, palladium chloride is effective at preventing plating failure when electroless plating is performed in conditions in which plating failure is likely to occur.

The palladium catalyst providing step can be performed by bringing the catalyst providing solution into contact with the terminals by an immersion method, spraying method, etc., and then washing the terminals with water.

### <Electroless Nickel Plating Step (S3)>

As an electroless nickel plating bath used in this step, a plating bath containing, for example, a water-soluble nickel salt, reducing agent and complexing agent can be used. Electroless nickel plating bath is explained in, for example, JP-A No. H08-269726 in detail.

As the water-soluble nickel salt, a nickel sulfate, nickel chloride or the like is used in a concentration of about 0.01 to 1 mol/L.

As the reducing agent, a hypophosphorous acid, hypophosphite such as sodium hypophosphite, dimethylamine borane, trimethylamine borane, hydrazine or the like is used in a concentration of about 0.01 to 1 mol/L.

As the complexing agent, any of carboxylic acids such as malic acid, succinic acid, lactic acid, citric acid and sodium salts thereof, or an amino acid such as glycine, alanine, iminodiacetic acid, arginine and glutamine acid is used in a concentration of about 0.01 to 2 mol/L.

The plating bath is controlled to be at pH 4 to 7 and used at a bath temperature of about 40 to 90° C. When a hypophosphorous acid is used as the reducing agent in the bath, the following major reaction is promoted on the copper terminal surface by the Pd catalyst to form a Ni plating film:

Ni²⁺+H₂PO₂⁻+H₂O+2e⁻→Ni+H₂PO₃⁻+H₂

### <Electroless Palladium Plating Step (S4)>

As an electroless palladium plating bath used in this step, a plating bath containing, for example, a palladium compound, complexing agent, reducing agent and unsaturated carboxylic acid compound can be used.

As the palladium compound, for example, a palladium chloride, palladium sulfate, palladium acetate, palladium nitrate or tetraamminepalladium hydrochloride is used in a concentration of 0.001 to 0.5 mol/L by amount of the palladium standard.

As the complexing agent, for example, an ammonia or amine compound such as methylamine, dimethylamine, methylenediamine and EDTA is used in a concentration of about 0.001 to 10 mol/L.

As the reducing agent, for example, a hypophosphite or hypophosphite such as sodium hypophosphite and ammonium hypophosphite is used in a concentration of about 0.001 to 5 mol/L.

As the unsaturated carboxylic acid compound, for example, any of unsaturated carboxylic acids such as an acrylic acid, methacrylic acid and maleic acid, anhydrides thereof, salts thereof such as sodium salts and ammonium salts, and derivatives thereof such as ethyl esters and phenyl esters, is used in a concentration of about 0.001 to 10 mol/L.

The plating bath is controlled to be at pH 4 to 10 and used at a bath temperature of about 40 to 90° C. When a hypophosphorous acid is used as the reducing agent in the bath, the following major reaction is promoted on the copper terminal surface to form a Pd plating film:

Pd²⁺+H₂PO₂⁻+H₂O→Pd+H₂PO₃⁻+2H⁺

### <Electroless Gold Plating Step (S5)>

As an electroless gold plating bath used in the step, a plating bath containing, for example, a water-soluble gold compound, complexing agent and aldehyde compound can be used. Electroless gold plating bath is explained in, for example, JP-A No. 2008-144188 in detail.

As the water-soluble gold compound, a cyanide gold salt such as gold cyanide, gold potassium cyanide, gold sodium cyanide and gold ammonium cyanide is used in a concentration of about 0.0001 to 1 mol/L by amount of the gold standard.

As the complexing agent, for example, a phosphoric acid, boric acid, citric acid, gluconic acid, tartaric acid, lactic acid, malic acid, ethylenediamine, triethanolamine or ethylenediaminetetraacetic acid is used in a concentration of about 0.001 to 1 mol/L.

As the aldehyde compound (reducing agent), for example, an aliphatic saturated aldehyde such as formaldehyde and acetaldehyde, an aliphatic dialdehyde such as glyoxal and succindialdehyde, an aliphatic unsaturated aldehyde such as crotonaldehyde, an aromatic aldehyde such as benzaldehyde and o-, m- or p-nitrobenzaldehyde, or a sugar having an aldehyde group (—CHO) such as glucose and galactose, is used in a concentration of about 0.0001 to 0.5 mol/L.

The plating bath is controlled to be at pH 5 to 10 and used at a bath temperature of about 40 to 90° C. When the plating bath is used, the following two substitution reactions are promoted on the copper terminal surface to form an Au plating film:

Pd+Au⁺→Pd²⁺+Au+e⁻

and

e⁻ (obtained by oxidizing the components in the plating bath by the autocatalytic action of Au)+Au⁺→Au

<Abnormal Deposition Preventing Steps (S+a and S+b)>

The inventors of the present invention found the following problem: in the electroless palladium plating step (S4) of the above-described basic process, abnormal palladium deposition occurs on the resin surface around the terminals, that is, abnormal palladium deposition occurs in an area of the resin surface which supports the conductive circuit, the area being around the terminals.

The reason is not clear but is considered to be because it is difficult in the palladium catalyst providing step (S2) to completely remove the Pd²⁺ ions from the resin surface which is a support, while leaving selectively a sufficient amount of the metallic Pd attached to the terminal surface. It is considered that the Pd²⁺ ions left on the resin surface are reduced to zero-valent Pd in the electroless palladium plating bath and the resulting Pd acts as cores and grows to metallic Pd particles. The reason why the abnormal deposition occurs particularly and restrictedly on the resin surface around the terminals is supposed to be because reaction reactivity of the plating solution is high around of the terminals, so that nickel is eluted from the nickel plating film and substitution from Ni to Pd (eluted Ni+Pd²⁺ on the resin surface→Ni²⁺+Pd) occurs frequently on the resin surface around a nickel eluting point.

In plating method of the present invention, to inhibit or prevent such abnormal deposition, one or more surface treatments selected from the treatment with the solution of pH 10 to 14 and the plasma treatment is performed on the terminals or the resin surface around the terminals at the optional step after the step of providing the palladium catalyst and before the step of performing electroless palladium plating.

By the treatment with the solution of pH 10 to 14 or plasma, the material which comprises the resin surface that supports the conductive circuit is appropriately removed to roughen the resin surface. The Pd²⁺ ions attached to the resin surface around the circuit are removed by any of the treatments together with the material. This is supposed to be the reason why the abnormal deposition is prevented.

As the treatment with the solution of pH 10 to 14, one or more treatments selected from the group consisting of, for example, a treatment with a sodium hydroxide-containing solution, treatment with a permanganate-containing solution, treatment with a sulfur organic substance-containing solution, treatment with a potassium cyanide (KCN)-containing solution and treatment with a sodium cyanide (NaCN)-containing solution can be performed. After the solutions are brought into contact with the terminals by an immersion method or spraying method, the terminals can be washed off with water.

The treatment with the solution of pH 10 to 14 or plasma is effective for roughening a common resin material comprising the core substrate or insulating layer.

As the resin material which comprises the core substrate or insulating layer and supports the conductive circuit, there may be mentioned a thermosetting resin such as an epoxy resin composition, cyanate resin composition, polyimide resin composition, polyamide resin composition and acrylate resin composition, and a thermoplastic resin, for example.

Hereinafter, the surface treatments with the solutions and the plasma treatment will be described in sequence.

(1) Surface Treatment with a Sodium Hydroxide-Containing Solution

As the sodium hydroxide-containing solution, there may be used a simple NaOH aqueous solution controlled to be in a concentration in which the solution is a strongly-alkaline solution of pH 10 to 14. The pH of the solution can be measured by putting a pH meter provided with an electrodes in the bath.

Also, a mixed solution comprising NaOH and an ethylene glycol-based solvent-containing solution, which is an acidic solution such as an NaOH-containing alkaline buffer for surface wetting, can be used as long as it is in a concentration capable of making the mixed solution be a strongly-alkaline mixed solution of pH 10 to 14. As the ethylene glycol-based solvent-containing solution to be mixed with NaOH, there may be mentioned Swelling Dip Securiganth P make up solution manufactured by Atotech Japan, for example.

(2) Surface Treatment with a Permanganate-Containing Solution

The permanganate-containing solution can be controlled to be at pH 10 to 14 and strongly alkaline, depending on the added amount of NaOH.

The permanganate-containing solution roughens the resin surface by the following oxidization reactions:

CH₄+12MnO₄⁻+14OH⁻→CO₃²⁻+12MnO₄²⁻+9H₂O+O₂

2MnO₄²⁻+2H₂O→2MnO₂+4OH⁻+O₂

In the reaction formulae, CH₄ means a resin molecule.

As the permanganate-containing solution, for example, Concentrate Compact CP make up solution (a NaMnO₄-containing oxidizing agent manufactured by Atotech Japan) can be mixed in combination with NaOH that is an OH source.

(3) Surface Treatment with a Sulfur Organic Substance-Containing Solution

The sulfur organic substance-containing solution can be controlled to be at pH 10 to 14 and strongly alkaline by the addition of a 5% NaOH aqueous solution and 5% HCl aqueous solution, for example.

The sulfur organic substance not only functions to roughen the resin surface but also is able to, when being brought into contact with the resin surface, cause a reaction with the Pd²⁺ attached to the resin surface to form complex ions and thus inactivate the Pd²⁺. This is supposed to be the reason why the abnormal deposition is prevented.

As the sulfur organic substance, sulfur organic substances containing a sulfur atom and carbon atom can be used without any particular limitation; however, those containing a sulfur such as sodium thiosulfate but not containing a carbon atom cannot be used. Such sulfur organic substances include a thiourea derivative, thiols, a sulfide, thiocyanates, a sulfamic acid and salts thereof.

Specific examples of the thiourea derivative include thiourea, diethylthiourea, tetramethylthiourea, 1-phenyl-2-thiourea and thioacetamide.

Specific examples of the thiols include 2-mercaptoimidazole, 2-mercaptothiazoline, 3-mercapto-1,2,4-triazole, mercaptobenzimidazole, mercaptobenzoxazole, mercaptobenzothiazole and mercaptopyridine.

Specific examples of the sulfide include 2-aminophenyl disulfide, tetramethylthiuram disulfide and a thiodiglycolic acid.

Specific examples of the thiocyanates include sodium thiocyanate, potassium thiocyanate and ammonium thiocyanate.

Specific examples of the sulfamic acid and salts thereof include sulfamic acid, ammonium sulfamate, sodium sulfamate and potassium sulfamate.

Among these sulfur organic substances, thiols having a mercapto group or thiocyanates having a thiocyano group are preferred.

Concentration of the sulfur organic substance is preferably 0.1 to 100 g/L, particularly preferably 0.2 to 50 g/L.

(4) Surface Treatment with a Potassium Cyanide (KCN)-Containing Solution

The potassium cyanide (hereinafter may be referred to as KCN)-containing solution can be controlled to be at pH 10 to 14 and strongly alkaline, depending on the concentration of KCN.

The KCN-containing solution not only functions to roughen the resin surface but also is able to, when being bought into contact with the resin surface, cause a reaction with the Pd²⁺ attached to the resin surface to form CN⁻ complex ions, [Pd(CN)₃]⁻, and thus inactivate the Pd²⁺. This is supposed to be the reason why the abnormal deposition is prevented.

As the KCN-containing solution, a strongly-alkaline solution containing only KCN can be used.

(5) Surface Treatment with a Sodium Cyanide (NaCN)-Containing Solution

The sodium cyanide (hereinafter may be referred to as NaCN)-containing solution can be controlled to be at pH 10 to 14 and strongly alkaline depending on the concentration of NaCN.

The reason why the NaCN-containing solution prevents the abnormal deposition is supposed to be because of the same mechanism as the KCN-containing solution.

As the NaCN-containing solution, a strongly-alkaline solution containing only NaCN can be used.

### (6) Plasma Treatment

The plasma treatment is a treatment to, by bringing the target surface into contact with plasma, oxidize, decompose and remove a smear on the copper terminal surface, as well as to appropriately remove the material comprising the resin surface that supports the circuit to roughen the surface.

The Pd²⁺ ions attached to the resin surface around the circuit are removed by the plasma treatment together with the material. This is supposed to be the reason why the abnormal deposition is prevented.

As a plasma treatment device, for example, PCB2800E (manufactured by March Plasma Systems, Inc.) can be used. Specific method and condition of the plasma treatment are as follows, for example:

### <Plasma Treatment Condition>

Gas: CF₄/O₂ (two-component mixture) or CF₄/O₂/Ar (three-component mixture)

Ambient gas pressure: 10 to 500 mTorr

Output: 1,000 W to 10,000 W

Time: 60 to 600 seconds

The plating method of the present invention is carried out by the process described above. By the plating method, a high quality Ni—Pd—Au plating film is formed on the terminals of the circuit of the outermost layer of the printed wiring board, and also is obtained a high-quality plated surface in which no abnormal deposition is present on the resin surface around the terminals.

A semiconductor apparatus can be produced by mounting a semiconductor package on the printed wiring board having the terminals plated by the plating method of the present invention thereon. Also, a semiconductor package can be produced by using the interposer obtained by the present invention as the package substrate, mounting a semiconductor device on the interposer, connecting them to each other and encapsulating them. Examples of the semiconductor package structure which uses an interposer as the package substrate include those shown in FIGS. 1 and 2. The semiconductor package comprising such an interposer can be produced by a conventionally known method.

A semiconductor apparatus with high connection reliability is obtained by using the printed wiring board having the terminals plated by the plating method of the present invention thereon.

### EXAMPLES

Hereinafter, the present invention will be described further in detail with reference to examples. The scope of the present invention is not limited to the examples, however.

### (Test Piece Production)

Common test pieces (substrates with a copper circuit) to be used in examples and comparative examples described below were prepared by the following steps.

(1) A copper-clad laminate having a 3 μm-copper foil (MCL-E-679FG manufactured by Hitachi Chemical Co., Ltd., total thickness 0.1 mm) is surface-treated with a 5% hydrochloric acid.

(2) A dry film for semi-additive process (UFG-255 manufactured by Asahi Kasei Corporation) is laminated to the copper foil surface of the copper-clad laminate by means of a roll laminator.

(3) The dry film is exposed to light in a predetermined pattern (collimated light exposure device: EV-0800 manufactured by ONO SOKKI CO., LTD., exposure condition: 140 mJ, holding time: 15 minutes) and developed (developer: 1% sodium carbonate aqueous solution, developing time: 40 seconds). Electrolytic copper plating is performed on a portion which is exposed in the form of the pattern to form a 20 μm-thick electrolytic copper plating film, and then the dry film is removed therefrom (stripper: R-100 manufactured by Mitsubishi Gas Chemical Company, Inc., removing time: 240 seconds).

(4) After the removal, the 3 μm-copper foil (seed layer) is removed by flash etching with SAC Process (etching solution) manufactured by EBARA-UDYLITE CO., LTD.)

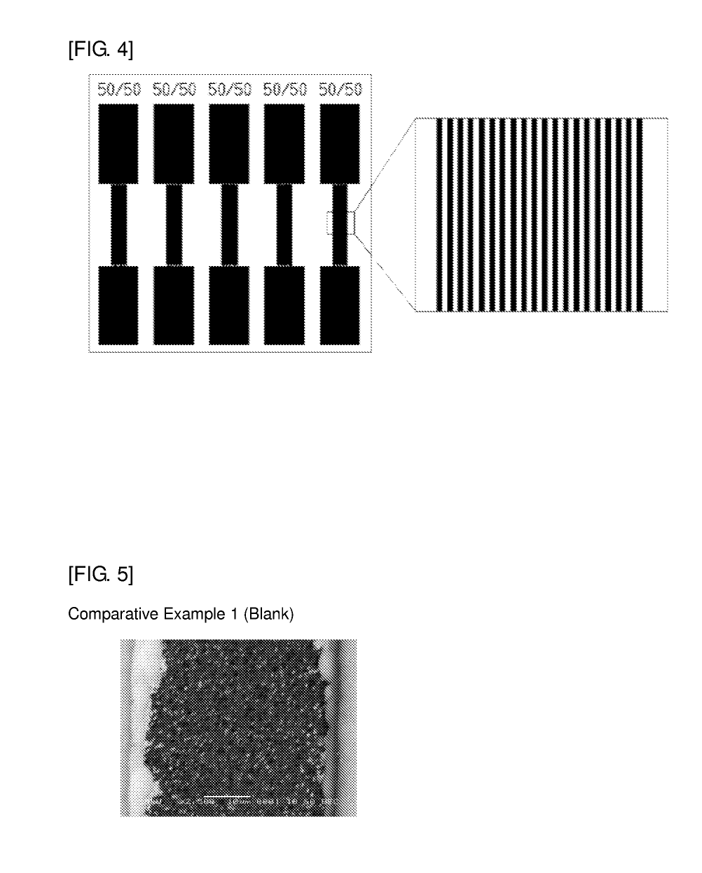

(5) Then, a circuit roughening treatment (roughening solution: CZ8101 manufactured by MEC COMPANY LTD., roughening condition: 1 μm) is performed, thereby producing test pieces having a comb-shaped copper circuit that has lines and spaces (L/S) of 50 μm/50 μm. FIG. 4 shows the comb-shaped copper circuit formed on the test pieces.

### Comparative Example 1

### Blank

An ENEPIG process was carried out by the following steps, which is common with Examples described below.

(1) Cleaner Treatment Step

Using ACL-007 manufactured by C. Uyemura & Co., Ltd. as the cleaner solution (cleaner), the test piece was immersed in the cleaner solution at a solution temperature of 50° C. for five minutes and then washed with water three times.

(2) Soft Etching Step

After the cleaner treatment step, using a mixed solution of sodium persulfate and sulfuric acid as the soft etching solution, the test piece was immersed in the soft etching solution at a solution temperature of 25° C. for one minute and then washed with water three times.

(3) Acid Cleaning Step

After the soft etching step, the test piece was immersed in a sulfuric acid at a solution temperature of 25° C. for one minute and then washed with water three times.

(4) Pre-Dip Step

After the acid cleaning step, the test piece was immersed in a sulfuric acid at a solution temperature of 25° C. for one minute.

(5) Palladium Catalyst Providing Step

After the pre-dip step, to provide a palladium catalyst to terminals, KAT-450 manufactured by C. Uyemura & Co., Ltd. was used as a palladium catalyst providing solution. The test piece was immersed in the palladium catalyst providing solution at a solution temperature of 25° C. for two minutes and then washed with water three times.

(6) Electroless Ni Plating Step

After the palladium catalyst providing step, the test piece was immersed in an electroless Ni plating bath (NPR-4 manufactured by C. Uyemura & Co., Ltd.) at a solution temperature of 80° C. for 35 minutes and then washed with water three times.

(7) Electroless Pd Plating Step

After the electroless Ni plating step, the test piece was immersed in an electroless Pd plating bath (TPD-30 manufactured by C. Uyemura & Co., Ltd.) at a solution temperature of 50° C. for five minutes and then washed with water three times.

(8) Electroless Au Plating Step

After the electroless Pd plating step, the test piece was immersed in an electroless Au plating bath (TWX-40 manufactured by C. Uyemura & Co., Ltd.) at a solution temperature of 80° C. for 30 minutes and then washed with water three times.

### Example 1

### Surface Treatment with a Sodium Permanganate-Containing Solution

One of the common test pieces underwent the ENEPIG process of Comparative Example 1, except that after the palladium catalyst providing step and before the electroless Ni plating step, a surface treatment was performed on the test piece by the following steps with a sodium permanganate-containing solution.

(1) Resin Surface Roughening Step

The test piece was immersed in a sodium permanganate-containing roughening solution (NaOH: 40 g/L, Concentrate Compact CP make up solution manufactured by Atotech Japan: 580 mL/L, pH=12.5) at a solution temperature of 80° C. for two minutes and then washed with water three times.

(2) Neutralizing Step

After the roughening step, the test piece was immersed in a neutralizing solution (Reduction Securiganth P500 make up solution manufactured by Atotech Japan) at a solution temperature of 40° C. for three minutes and then washed with water three times.

### Example 2

### Surface Treatment with an NaOH-Containing Alkaline Buffer for Surface Wetting and Sodium Permanganate-Containing Solution

One of the common test pieces underwent the ENEPIG process of Comparative Example 1, except that after the palladium catalyst providing step and before the electroless Ni plating step, a surface treatment was performed on the test piece by the following steps with an NaOH-containing alkaline buffer for surface wetting and sodium permanganate-containing solution.

(1) Resin Surface Swelling Step

The test piece was immersed in a mixed solution (pH 12) of a commercially-available sodium hydroxide (3 g/L) and ethylene glycol-based solvent containing solution (500 mL/L, Swelling Dip Securiganth P make up solution manufactured by Atotech Japan) at a solution temperature of 60° C. for two minutes and then washed with water three times.

(2) Resin Surface Roughening Step

After the swelling step, the test piece was immersed in a sodium permanganate-containing roughening solution (NaOH: 45 g/L, Concentrate Compact CP make up solution manufactured by Atotech Japan: 0.58 L/L, pH 14) at a solution temperature of 80° C. for two minutes and then washed with water three times.

(3) Neutralizing Step

After the roughening step, the test piece was immersed in a neutralizing solution (Reduction Securiganth P500 make up solution manufactured by Atotech Japan) at a solution temperature of 40° C. for three minutes and then washed with water three times.

### Example 3

### Plasma Treatment

One of the common test pieces underwent the ENEPIG process of Comparative Example 1, except that after the electroless Ni plating step and before the electroless Pd plating step, a plasma treatment was performed on the test piece using the following device and in the following condition.

Device: PCB2800E (manufactured by March Plasma Systems, Inc.)

Condition: Gas (two-component mixture): O₂ (95%)/CF₄ (5%), Ambient pressure: 250 mTorr, Watt: 2,000 W, Time: 75 seconds

### Example 4

### Surface Treatment with a KCN-Containing Solution

One of the common test pieces underwent the ENEPIG process of Comparative Example 1, except that after the palladium catalyst providing step and before the electroless Ni plating step, the test piece was immersed in a KCN-containing solution (pH 12) in a concentration of 20 g/L and at a solution temperature of 25° C. for one minute and then washed with water three times.

### Example 5

### Surface Treatment with a Sulfur Organic Substance-Containing Solution

One of the common test pieces underwent the ENEPIG process of Comparative Example 1, except that after the palladium catalyst providing step and before the electroless Ni plating step, a surface treatment was performed with a sulfur organic substance-containing solution.

As the sulfur organic substance-containing solution, an aqueous solution containing mercaptothiazoline of 1 g/L (pH 12.5) was used.

### Example 6

### With a Copper-Clad Laminate LαZ-4785GS-B

One of the common test pieces was treated in the same manner as in Example 1, except that the copper-clad laminate (MCL-E-679FG manufactured by Hitachi Chemical Co., Ltd.) was altered to a copper-clad laminate having a 3 μm-copper foil (LαZ-4785GS-B manufactured by Sumitomo Bakelite, Co., Ltd., total thickness 0.1 mm).

### (Evaluation)

Terminals of the ENEPIG plated products obtained in Examples and Comparative Example were observed using an electron microscope (backscattered electron images) to evaluate the quality between lines.

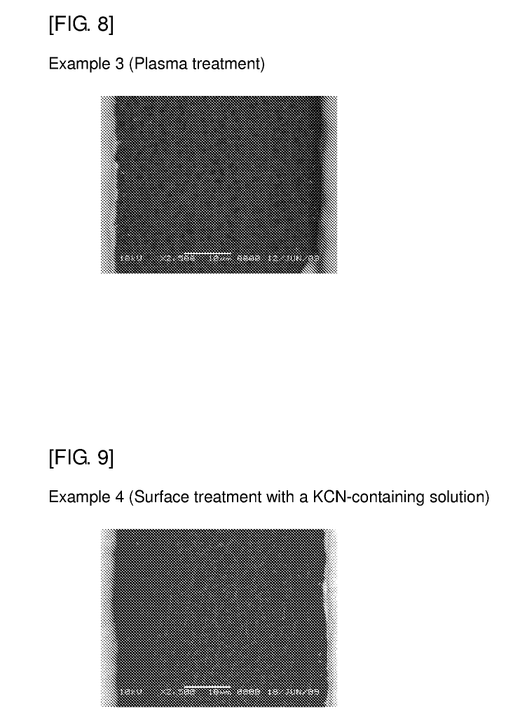

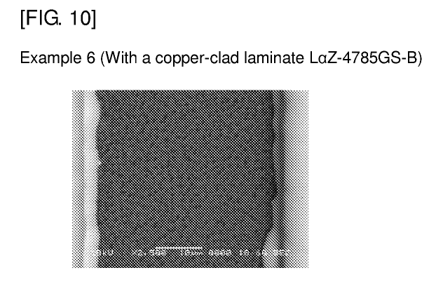

FIGS. 5 to 10 show electron micrographs of Comparative Example 1 and Examples 1 to 4 and 6. Comparative Example 1 (FIG. 5) is a blank experiment and extremely abnormal deposition occurred on the resin surface around the terminals (between lines).

Each electron micrograph shows two terminals (lines) at left and right ends of the photographic image, the terminals extending vertically, and a space between the lines (black space shown in the image), in which the resin surface is exposed. In Comparative Example 1, many white dots of abnormally deposited metal were observed in this space. Extremely excessive deposition was observed around the border of each terminal (line).

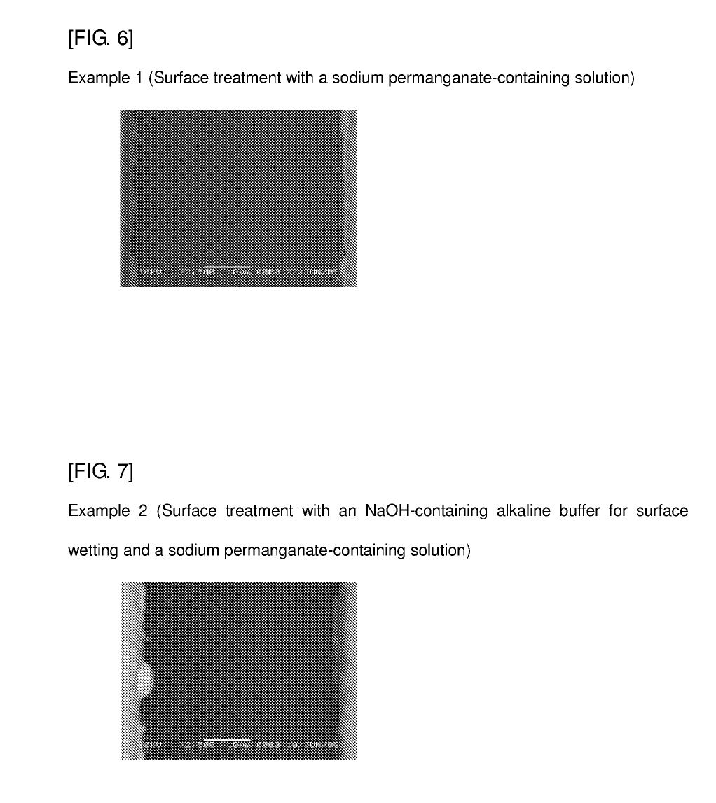

In contrast, in Examples 1 to 4 and 6 (FIGS. 6 to 10), no abnormal deposition occurred on the resin surface around the terminals. The micrograph of Example 5 (the treatment with the sulfur organic substance-containing solution) is not attached herewith; however, as in other Examples, no abnormal deposition was observed on the resin surface around the terminals.

1. A method for electroless nickel-palladium-gold plating on a substrate with a fine metal pattern in which the fine metal pattern is provided on a supporting resin surface, the method comprising the steps of providing a palladium catalyst to the fine metal pattern and then performing electroless nickel-palladium-gold plating on the fine metal pattern,
wherein at least one surface treatment selected from a treatment with a solution of pH 10 to 14 and a plasma treatment is performed on the substrate with the fine metal pattern at an optional step after the step of providing a palladium catalyst and before the step of performing electroless palladium plating.

2. The method for electroless nickel-palladium-gold plating according to claim 1, wherein the substrate with the fine metal pattern is a printed wiring board, and the fine metal pattern is a conductive circuit on a surface of the printed wiring board.

3. The method for electroless nickel-palladium-gold plating according to claim 2, wherein the printed wiring board is a motherboard, and the conductive circuit in a plated area thereof has lines and spaces (L/S) of 300 to 500 μm/300 to 500 μm.

4. The method for electroless nickel-palladium-gold plating according to claim 2, wherein the printed wiring board is an interposer.

5. The method for electroless nickel-palladium-gold plating according to claim 4, wherein the conductive circuit in a plated area of a surface of the interposer has lines and spaces (L/S) of 10 to 50 μm/10 to 50 μm, the surface being on a side to be connected to a semiconductor device.

6. The method for electroless nickel-palladium-gold plating according to claim 4, wherein the conductive circuit in a plated area of a surface of the interposer has lines and spaces (L/S) of 300 to 500 μm/300 to 500 μm, the surface being on a side to be connected to a motherboard.

7. A plated product in which a nickel-palladium-gold plated layer is formed on, of a substrate with a fine metal pattern in which the fine metal pattern is provided on a supporting resin surface, a surface of the fine metal pattern by the method defined in claim 1.

8. A printed wiring board in which a nickel-palladium-gold plated layer is formed on a conductive circuit on a surface thereof by the method defined in claim 1.

9. The printed wiring board according to claim 8, wherein a part of the conductive circuit which has the nickel-palladium-gold plated layer has lines and spaces (L/S) of 300 to 500 μm/300 to 500 μm.

10. An interposer in which a nickel-palladium-gold plated layer is formed on a conductive circuit on a surface thereof by the method defined in claim 1.

11. The interposer according to claim 10, wherein the conductive circuit in a plated area of a surface of the interposer has lines and spaces (L/S) of 10 to 50 μm/10 to 50 μm, the surface being on a side to be connected to a semiconductor device.

12. The interposer according to claim 10, wherein the conductive circuit in a plated area of a surface of the interposer has lines and spaces (L/S) of 300 to 500 μm/300 to 500 μm, the surface being on a side to be connected a motherboard.

13. A semiconductor apparatus comprising a semiconductor device mounted on the printed wiring board defined in claim 8.

14. A semiconductor apparatus comprising a semiconductor device mounted on, of a printed wiring board comprising the interposer defined in claim 10, the interposer.
